(19) United States
(12) Patent Application Publication
(10) Pub. No.: US 2017/0243774 A1
(43) Pub. Date: Aug. 24, 2017

(54) METHOD AND APPARATUS FOR FORMING POROUS SILICON LAYERS

(71) Applicant: APPLIED MATERIALS, INC., Santa Clara, CA (US)

(72) Inventors: Takao YONEHARA, Sunnyvale, CA (US); Matthew SIMAS, Hayward, CA (US); Jonathan S. FRANKEL, San Jose, CA (US)

(21) Appl. No.: 15/506,814

(22) PCT Filed: Sep. 4, 2015
(86) PCT No.: PCT/US2015/048644

§ 371 Date: Feb. 27, 2017

Related U.S. Application Data
(60) Provisional application No. 62/046,152, filed on Sep. 4, 2014.

(51) Int. Cl. H01L 21/673; C25D 11/00; C25D 17/06; H01L 21/3063; C25D 11/32

(52) U.S. Cl. CPC H01L 21/67326; H01L 21/3063; C25D 11/32; C25D 17/06; C25D 11/005

(57) ABSTRACT

Methods and apparatus for forming porous silicon layers are provided. In some embodiments, an anodizing bath includes: a housing having a first volume to hold a chemical solution; a cathode disposed within the first volume at a first side of the housing; an anode disposed within the first volume at a second side of the housing, opposite the first side, wherein a face of each of the cathode and the anode have a given surface area; a substrate holder configured to retain a plurality of substrates along a perimeter thereof within the first volume in a plurality of substrate holding positions, a plurality of vent openings fluidly coupled to the first volume to release process gases, wherein a top of each of the plurality of vent openings are disposed above a chemical solution fill level in the first volume.

### FIELD

Embodiments of the present disclosure generally relate to semiconductor processing, and more specifically, to methods and apparatus for forming porous silicon layers.

### BACKGROUND

Crystalline silicon (including multi- and mono-crystalline silicon) is the most dominant absorber material for commercial solar photovoltaic (PV) applications, currently accounting for well over 80% of the solar PV market. There are different known methods of forming monocrystalline silicon film and releasing or transferring the grown semiconductor (e.g., monocrystalline silicon) layer. Regardless of the methods, a low cost epitaxial silicon deposition process accompanied by high-volume, production-worthy low cost methods of release layer formation are prerequisites for the wider use of silicon solar cells. Furthermore, reduction of cost and release layer formation by porous Si is crucial for high volume production.

Porous silicon (PS) formation is a fairly new field with an expanding application landscape. Porous silicon is created by the electrochemical etching of silicon wafers with appropriate doping in an electrolyte bath. The electrolyte for porous silicon is: hydrogen fluoride (HF) (49% in H2O typically), isopropyl alcohol (IPA) (and/or acetic acid), and deionized water (DI H2O). IPA (and/or acetic acid) serves as a surfactant and assists in the uniform creation of porous silicon. Additional additives such as certain salts may be used to enhance the electrical conductivity of the electrolyte, thus reducing heating and power consumption through ohmic losses.

Porous silicon has been used as a sacrificial layer in MEMS and related applications, where there is a much higher tolerance for cost per unit area of the wafer and resulting product than solar PV. Typically porous silicon is produced on simpler and smaller single-wafer electrochemical process chambers with relatively low throughputs on smaller wafer footprints. Currently there is no commercially available porous silicon equipment that allows for a high throughput, cost effective porous silicon manufacturing. The viability of the technology in solar PV applications hinges on the ability to industrialize the process to large scale (at much lower cost), needing development of very low cost-of-ownership, high-productivity porous silicon manufacturing equipment.

Thus, the inventors have provided methods and apparatus for forming porous silicon layers with high throughput at high volume with decreased cost.

### SUMMARY

Embodiments of methods and apparatus for forming porous silicon layers are provided herein. In some embodiments, an anodizing bath includes: (a) a housing having a first volume to hold a chemical solution and a longitudinal axis along a length of the housing; (b) a cathode disposed within the first volume at a first side of the housing; (c) an anode disposed within the first volume at a second side of the housing, opposite the first side, wherein a face of each of the cathode and the anode have a given surface area; (d) a substrate holder configured to retain a plurality of substrates along a perimeter of the substrates within the first volume in a plurality of substrate holding positions in an orientation such that faces of the substrates are substantially normal to the longitudinal axis, wherein the substrate holder is configured to retain substrates having a given surface area of a face of the substrate that is substantially equal to the given surface area of the faces of the anode and cathode, wherein a first substrate holding position is disposed at a first distance from the cathode, a second substrate holding position is disposed at a second distance from the anode, and remaining substrate holding positions are disposed between the first and second substrate holding positions, wherein the first distance and the second distance are each less than or equal to a distance between adjacent ones of the plurality of substrate holding positions, wherein the substrate holder forms a seal around the perimeter of each substrate to form a plurality of second volumes between adjacent pairs of the plurality of substrates when substrates are disposed within the substrate holder; and (e) a plurality of vent openings fluidly coupled to the first volume to release process gases, wherein a top of each of the plurality of vent openings are disposed above a chemical solution fill level in the first volume.

In some embodiments, a method of transferring substrates into an anodizing bath includes providing a cassette holding a plurality of substrates a first distance apart; transferring the plurality of substrates from the cassette to a substrate alignment tray; orienting an upper portion of a substrate holder above the plurality of substrates, wherein the upper portion of the substrate holder comprises a plurality of first bodies and a corresponding plurality of second bodies; applying a first force to each first body to move each first body toward each corresponding second body; applying a second force to each second body to move each second body toward each corresponding first body until each first body and second body form a seal around a perimeter of each substrate; lowering the upper portion into a housing having a first volume configured to hold a chemical solution to immerse the substrates in a chemical solution, wherein the first volume comprises a lower portion of the substrate holder disposed along a bottom surface of the housing; applying a force to the upper portion of the substrate holder in a direction perpendicular to the bottom surface of the housing while the substrates are immersed in the chemical solution; applying a current to a cathode disposed within the first volume at a first end of the housing and to an anode disposed within the first volume at a second end of the housing, opposite the first end to form porous Si on the substrates, wherein a diameter of the cathode and the anode is equal to the diameter of the substrates; removing the substrates from the housing; exposing the substrates to an isopropyl alcohol rinse; exposing the substrates to a deionizing water, quick dump rinse; and exposing the substrates to a spin drying process.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a single-wafer porous silicon electrolytic bath arrangement.

FIG. 2 depict an n-batch stack series array porous silicon electrolytic bath arrangement typically utilized in the industry.

FIGS. 3A-3C depict a top view, side-view, and perspective view of a substrate holder disposed within a bath in accordance with some embodiments of the present disclosure.

FIG. 4 depicts the lower portion of the substrate holder in accordance with some embodiments of the present disclosure.

FIG. 5 depicts the lower portion of the substrate holder with a plurality of substrates in accordance with some embodiments of the present disclosure.

FIG. 6 depicts the upper portion of the substrate holder in accordance with some embodiments of the present disclosure.

FIG. 7 depicts the intersection of the first sealing material and the second sealing material when the upper portion is disposed atop the lower portion in accordance with some embodiments of the present disclosure.

FIG. 8 depicts a plurality of substrate holders in accordance with some embodiments of the present disclosure.

FIG. 9 depicts one embodiment of a bath in bath design typically utilized in the industry.

FIG. 10 depicts one embodiment of a bath in bath design arrangement typically utilized in the industry.

FIG. 11 depicts an anodizing bath configuration, in accordance with some embodiments of the current disclosure.

FIGS. 12A-12B depict an upper portion of a substrate holder in accordance with some embodiments of the current disclosure.

FIG. 13A-13D depicts a method of transferring substrates into and out of an anodizing bath configuration in accordance with some embodiments of the current disclosure.

FIG. 14A-14C depicts an anodizing bath configuration, in accordance with some embodiments of the current disclosure.

FIG. 15 depicts a substrate holder in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of methods and apparatus for forming porous silicon layers are provided herein. In at least some embodiments, the inventive methods and apparatus disclosed herein may advantageously provide high throughput production of porous silicon layers at low cost with full porous silicon layer coverage on both sides of a substrate. In addition, the inventive methods may further advantageously provide enhanced batch substrate processing by reducing the time for filling and draining chemical solution from the batch processing reactor. While not intending to be limiting, the inventors have observed that the inventive methods and apparatus may be particularly advantageous in applications such as solar photovoltaics, semiconductor microelectronics, micro-electro-mechanical systems (MEMS), and optoelectronics. In the field of photovoltaics, the current disclosure enables high-productivity fabrication of semiconductor-based sacrificial separation layers (made of porous semiconductors such as porous silicon), buried optical reflectors (made of multi-layer/multi-porosity porous semiconductors such as porous silicon), formation of porous semiconductor (such as porous silicon) for anti-reflection coatings, passivation layers, and multijunction, multi-band gap solar cells (for instance, by forming a wider band gap porous silicon emitter on crystalline silicon thin film or wafer based solar cells). In the semiconductor field, inventive methods and apparatus enables fabrication of silicon on insulator substrate for high speed and RF devices as well as sacrificial MEMS separation layers for die detachment, and shallow trench isolation (STI) porous silicon (using porous silicon formation with an optimal porosity and subsequent oxidation). Other applications of porous Si include three dimensional integration of Si microelectronics. An epitaxial active layer is able to be deposited epitaxially upon the porous Si, which increases the device packing density due to the three dimensional integrated circuit (IC) integration and design compared with conventional two dimensional ICs. Other applications include the general fields of MEMS, including sensors and actuators, stand-alone, or integrated with integrated semiconductor microelectronics.

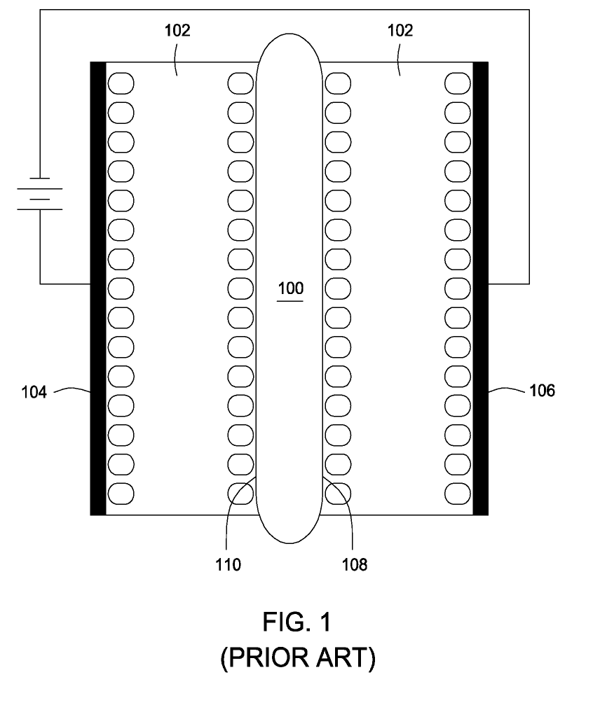

FIG. 1 shows a very basic diagram of a single substrate porous silicon electrolytic bath arrangement (prior art). Substrate 100 is placed in electrolyte bath 102 (i.e. a chemical solution), between anode 104 and cathode 106. In one embodiment, the electrolyte bath 102 may be a hydrogen fluoride/isopropyl alcohol (HF/IPA) solution. In some embodiments, the chemical solution is premixed before filling the bath. The compositional ratio of HF, H₂O and IPA is monitored for automated spiking to stabilize the wafer yield and the life of the chemical solution resulting in the higher through-put at lower cost. A porous silicon film is created on the substrate frontside 108 as current is passed through the system; no porous silicon is formed on substrate backside 110. As current runs through the system, hydrogen gas may be evolved at cathode 106 and substrate backside 110 as well as at the anode 104; oxygen gas may be evolved at anode 104 and substrate frontside 108.

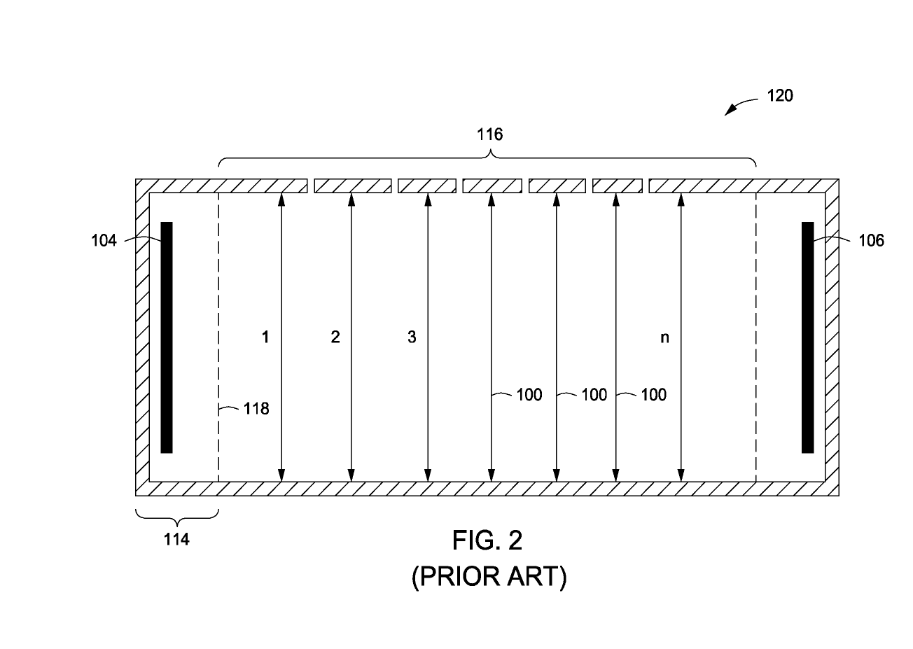

FIG. 2 reveals the basic form of the “n” batch stack series array that can be used in the industry (prior art). In the arrangement substrates 100, for example semiconductor wafers, are stacked substantially parallel with respect to one another and may be oriented vertically (or alternatively horizontally or in other orientations) with the electrode assembly on either end of the batch reactor 120 (i.e. the bath).

As depicted in FIG. 2, the electrode assembly is a compartmentalized electrode chamber 114. The electrode chambers 114 are separated from reaction chamber 116, which holds the electrolyte chemical solution and the substrates 100. The electrode chamber 114 is separated from the reaction chamber 116 by the means of conducting membrane 118 which allows an electric field to pass through but prevents the transfer of chemical ions and molecules that contaminate the substrate surface during anodization. The conducting membrane 118 can be self-standing or be sandwiched by some perforated non conducting plates to provide mechanical stability. The separation or compartmentalization allows for the use of different electrolyte chemical solutions (various compositions, chemical components, etc.) in the electrode chambers 114 and in the reaction chamber 116 without interfering with each other. The substrates 100 are anodized by passing current from the electrodes placed in a hydrogen fluoride (HF) chemical solution and, by changing the polarity of the current alternatively; both sides of the substrate surface can be anodized symmetrically resulting in less warp-age after porous Si formations which is an advantageous feature for dual sided epi on top of the both sided porous silicon formation. The porosity of the porous layers can be altered by changing the currents step wise, resulting in multiple layered structure (e.g. single, bi- and tri-layers) which is crucial to accumulate the internal stress at the interface of the layers with various porosities, which leads to better splitting capability with higher yield for epitaxial layer exfoliation from the porous silicon layers. Multiple baths systems may be applied for enhancing dramatically the throughput over 2000 wafers per hour in conjunction with dual sided porous Si formation.

The reaction chamber 116 shown in FIG. 2 holds substrates and electrolyte. In the reaction chamber 116 of FIG. 2, substrates 100 are held in place by substrate holders, such as a wafer clamp. The number of substrates can be increased from 1 to n (with n being a minimum of 2 and a maximum at least in the tens of substrate) and large number of substrates can be stacked just by increasing the length of the reactor. The maximum value of “n” is based on the acceptable size of the batch reactor for the optimal tool foot print, chemical utilization, suitable electric power for “n” wafers, etc. Processing multiple substrates advantageously reduces the cost-of-ownership (CoO) of the system. The advantages of the batch design include one or more of the ability to share the chemical solution, use a single pair of electrodes, and reduce overall materials/components in the multi-wafer scheme. Other further descriptions of embodiments of FIG. 2 are described in U.S. Patent Publication No. 2013/0180847 by Yonehara et. al. and published Jul. 18, 2013.

As seen in FIG. 2, all the elements, substrates and electrodes, are confined in a single batch reactor 120 which isolates each substrate and electrode. In typical porous silicon electrolytic bath arrangements currently utilized in the industry, as depicted in FIG. 2, the size of the electrodes is smaller than the size of the substrates 100 because the chemical solution in-between the substrates at the end of the reaction chamber 116 (i.e. the end substrates) and the electrode acts as an imaginary electrode on the end substrates to be anodized. However, the configuration utilizes some distance between the electrodes and the end substrates to dilute the electric power into the chemical solution via diffusion of the electric charges injected by the electrodes, thus utilizing a larger volume of chemical solution at both ends of the reaction chamber 116 consisting of the electrode portions.

Furthermore, the sealing at the perimeter of the substrates 100 should minimize the substrate pitch such that anodizing current is not blocked and shadowed with any surface sealing method. In addition, the sealing components should be tightly connected without leakage of the anodizing current flow and the electrolyte chemical solution to ensure the uniformity of porous Si layers by anodization as well as for safety reasons since the chemical solution (e.g., HF) in the bath is a highly toxic material.

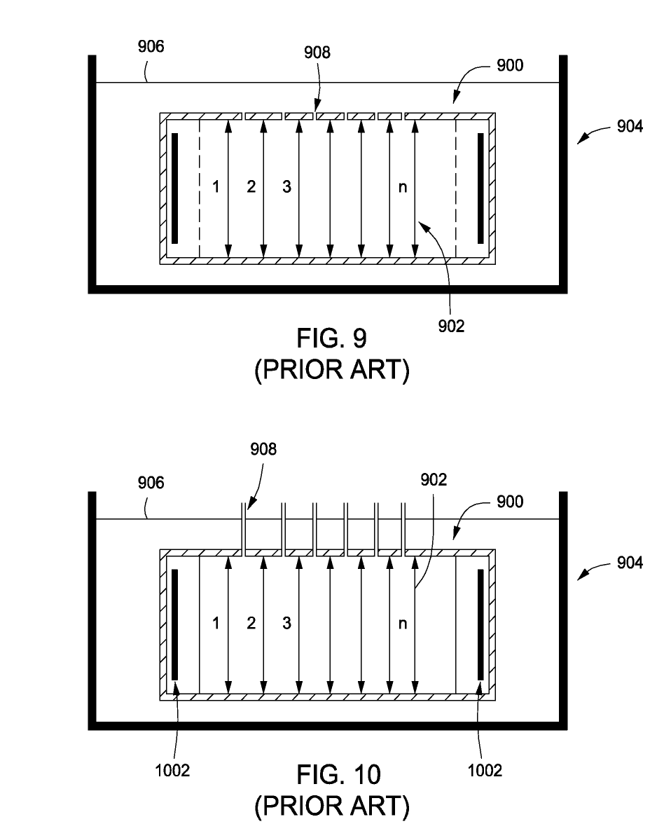

Typical wet chemical baths and process chambers use direct fluid fill/drain of the process chamber, wherein the chemical is directly pumped in the process chamber. Thus additional fill and drain times may be used before the process can start and results in loss of productivity. In some embodiments, a “bath in bath” design may be used. FIG. 9 and FIG. 10 depict two prior art embodiments of a bath in bath design (prior art). In some embodiments, as depicted in FIG. 9, a prefilled inner chamber is immersed and lifted out completely into and from the bath. In some embodiments, as depicted in FIG. 10, a resident bath-in-bath uses an auto loader that places a batch of substrates into the lower substrate holder part of the inside bath, and then retreats.

In the embodiment depicted in FIG. 9, the process chamber 900 is pre-loaded with substrates 902 and filled with the chemical solution 906. The entire process chamber 900 is then immersed into a larger bath 904 which is pre-filled with the chemical solution 906. The ports/vents 908 on the top of the process chamber 900 allow for the chemical solution 906 to fill the process chamber 900 if and when the liquid level drops in the process chamber 900 due to the reaction or other means of loss such as evaporation. However, in the configuration of FIG. 9, the anodizing current leaks in between the substrates 902, that should be isolated, through the ports/vents 908 during formation of porous Si layers, thus leading to non-uniformity of thickness and porosity in the porous Si layers. Once the process is complete, the process chamber 900 is pulled out of the larger bath 904 and a standby process chamber is immediately immersed in the larger bath 904 to minimize losses in productivity due to substrate load/unload and chamber fill and drain. The larger bath 904 is designed with a pumping and recirculation system to maintain suitable concentration and temperature. The methodology allows having multiple process chambers that can be introduced into the main bath without any loss in productivity.

In the other prior art embodiment depicted in FIG. 10, the process chamber 900 is an integral part of the tool or the larger bath 904 and is continuously immersed in the larger bath 904, but the process chamber 900 can open and close to accept load and unload substrates 902. Loading mechanisms such as robotic handlers can transfer a batch of n substrates 902 held in the substrate holders into the base of the process chamber 900. After the substrate handlers have moved away from the process chamber 900, the outer walls of the process chamber 900 closes. The action not only secures the substrates 902, but also encloses the chemical solution 906 in the process chamber 900. The additional ports/vents 908 allow the process chamber 900 to be filled completely to a suitable level and maintain the same level throughout the process. In any case, the top of the vents may be outside of the chemical solution 906, such that an electrically connecting path outside of the inner bath is avoided. The electrodes 1002 are located at the ends of the process chamber 900 isolated with the thin membrane as a diffusion barrier to electrode metal contaminants. As described in FIG. 2, the size of the electrodes 1002 is smaller than the substrates 902 thus utilizing some distance to dilute the electric power into the chemical solution 906 via diffusion of the electric charges injected by the electrodes 1002, which utilizes a larger volume of electrolyte (anodizing chemical solutions) at both ends of the chamber consisting of the electrode portions. Other further descriptions of embodiments of FIG. 9 and FIG. 10 are described in U.S. Patent Publication No. 2013/0180847 by Yonehara et. al. and published Jul. 18, 2013.

The inventors have observed that minimizing the total chemical volume advantageously reduces the electrolyte solution consumption and also improves substrate throughput and reduces downtime for replacing the electrolyte solution due to degradation of chemical activity. In order to reduce and minimize the chemical consumption in the bath, the period of the substrates as well as the distance between the substrate ends and the electrode should be reduced. The substrate pitch should also be carefully designed to allow reaction bubbles to be released toward the vent openings at the top of the substrates.

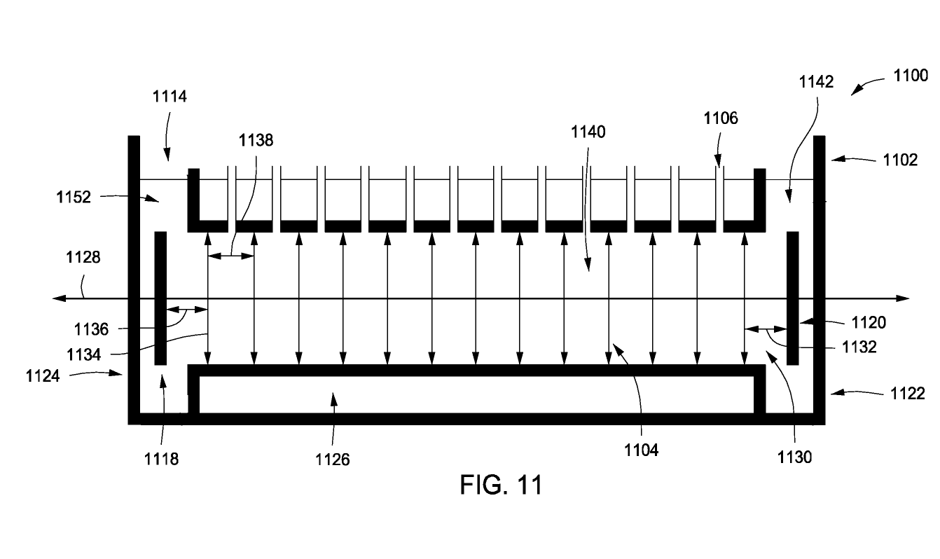

Thus, FIG. 11 depicts an anodizing bath 1100 configuration, in accordance with some embodiments of the current disclosure, having the advantageous features described above. FIG. 11 depicts an anodizing bath 1100 having a housing 1102. The housing 1102 has a first volume 1114. The first volume 1114 holds a suitable amount of chemical solution for forming porous Si on a plurality of substrates 1104. The housing 1102 has a longitudinal axis 1128 along a length of the housing 1102. The housing 1102 comprises a cathode 1120 within the first volume 1114. The cathode 1120 has a face with a given surface area. The housing 1102 comprises an anode 1118 within the first volume 1114. The anode 1118 has a face with a given surface area. The cathode 1120 is disposed at a first side 1122 of the housing 1102. The anode 1118 is disposed at a second side 1124 of the housing 1102 opposite the first side 1122. A substrate holder 1126 is configured to retain a plurality of substrates 1104 within the first volume 1114. The substrate holder 1126 is configured to retain the plurality of substrates 1104 along a perimeter of the substrates in a plurality of substrate holding positions. The substrates are held in an orientation such that faces of the substrates are substantially normal to the longitudinal axis 1128. Embodiments of a suitable substrate holder 1126 for use with an anodizing bath, such as anodizing bath 1100, are described below. The substrate holder is configured to retain substrates having a given surface area of a face of the substrate that is substantially equal to the given surface area of the faces of the anode and cathode (for example, a diameter, or width and length, of the cathode and anode is substantially equal to a diameter, or width and length, of the substrate). The inventors have observed that having the electrode size be substantially the same as the substrate size improves uniformity of layer formation and the reduces the consumption of the chemicals as compared to the configurations shown in FIGS. 2, 9, and 10. In some embodiments, the anode and cathode have a surface area of a face that is within about 10 percent of the surface area of a face of the substrate. In some embodiments, the anode and cathode have a surface area of a face that is about equal to the surface area of a face of the substrate.

The electrodes (i.e. anode 1118 and cathode 1120) are located within the first volume 1114 without any membrane or barrier (as described with respect to FIG. 2) between the electrodes 1118, 1120 and the substrates 1104 held by the substrate holder 1126. The substrate holder 1126 comprises a first substrate holding position 1130 a first distance 1132 from the cathode 1120 and a second substrate holding position 1134 a second distance 1136 from the anode. The remaining substrate holding positions are disposed between the first and second substrate holding positions 1130, 1334. The first distance 1132 and the second distance 1136 are each less than or equal to a distance 1138 between adjacent ones of the plurality of substrate holding positions. In some embodiments, the first distance 1132 between the first substrate holding position 1130 and the cathode 1120 is about 4 to about 12 mm, the second distance 1136 between the second substrate holding position 1134 and the anode 1118 is about 4 to about 12 mm, and the distance between each substrate inside the substrate holder 1126 is about 4 to about 12 mm. The inventors have observed that having the first distance 1132 and the second distance 1136 less than or equal to a distance 1138 between adjacent ones of the plurality of substrate holding positions advantageously improves uniformity of layer formation and reduces the consumption of chemical solution. The substrate holder 1126 forms a seal around the perimeter of each substrate 1104 to form to form a plurality of second volumes 1140 between adjacent pairs of the plurality of substrates when substrates are disposed within the substrate holder. The anodizing bath 1100 further comprises a plurality of vent openings 1106 fluidly coupled to the first volume 1114, and in some embodiments specifically to the plurality of second volumes 1140 between adjacent pairs of the plurality of substrates, to allow the release of process gases created during the porous Si formation. A top of each of the plurality of vent openings 1106 are disposed above a chemical solution fill level in the first volume

The electrodes 1118, 1120 are electrically separated by the substrate holder 1126, resulting in uniform charge flow toward the entire surface of the substrates 1104. The first volume comprises a third volume 1142 disposed between the first substrate holding position 1130 and the cathode 1120 and a fourth volume 1152 disposed between the second substrate holding position 1134 and the anode 1118. The chemical solution at or below the chemical solution fill level is isolated between each of the second volumes 1140, third volume 1142, and fourth volume 1152.

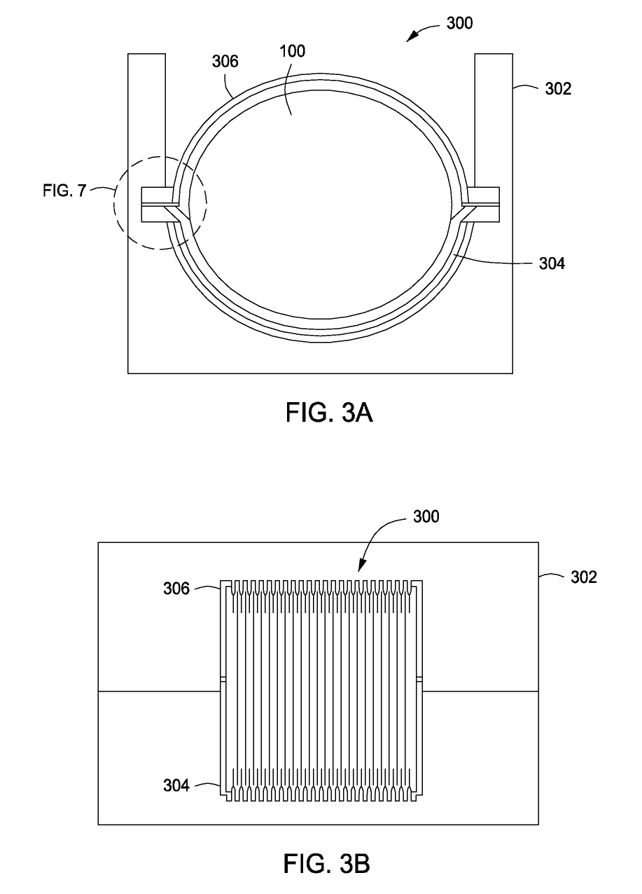

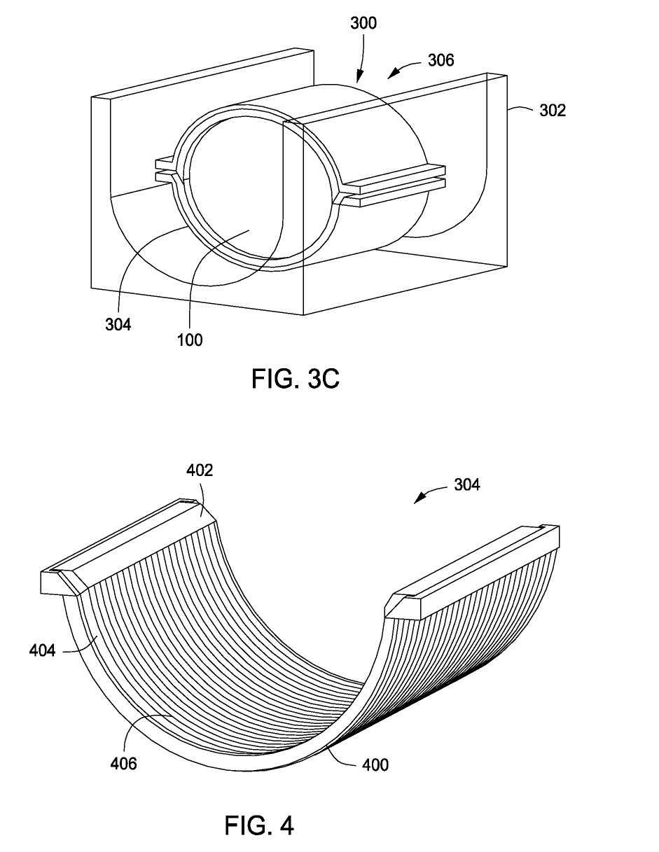

FIGS. 3A-3C depict a substrate holder 300 in accordance with some embodiments of the current disclosure, suitable for use with a bath configuration, such as depicted in FIG. 11. FIG. 3A depicts a front view of a substrate 100 held by substrate holder 300 and disposed within a bath 302. FIG. 3B depicts a side view of the substrate holder 300 disposed within the bath 302. FIG. 3C depicts a perspective view of the substrate holder 300 disposed within the bath 302.

The substrate holder 300 holds the substrates 100 and transports multiple substrates 100 into the bath 302. In some embodiments, substrates 100 are semiconductor wafers. While FIGS. 3A-3C depict a substrate holder 300 holding round substrates 100, a wide range of process chamber dimensions may be used to create porous silicon on substrates of various geometries such as, but not limited to round, square, pseudo square (square with truncated corners) with rounder corners of varying degrees, as well as rectangular structures. The substrates involved may be essentially flat with varying degree of roughness or may be structured to form 3-dimensional patterns or structured with films that locally inhibit or enable porous silicon formation. The number of substrates 100 held by the substrate holder 300 and bath 302 can be increased from 1 to n (with n being a minimum of 2 and a maximum at least in the tens of substrate) by increasing the length of the reactor. A symmetrical bath configuration can easily increase the number of substrates in the chamber-transportation tool, minimize the substrate pitch and form the dual sided porous Si on both sides of the substrates.

In some embodiments, the inner walls of the bath 302 may be lined with either a single layer of chemically inert (i.e. HF and organic resistant) insulating rubber or foam to provide a leak-free seal between the substrate holder 300 and the inner walls of the bath 302. The insulating layer advantageously minimizes or prevents chemical leakage or electric field leakage.

In some embodiments, as shown in FIGS. 3A-3C, the substrate holder 300 comprises a lower (i.e. bottom) portion 304 and an upper portion 306. The inventors have observed that having only an integral lower portion 304 and an integral upper portion 306 minimizes the number of junctions around the substrates 100, thus advantageously reducing the leakage current at the junctions around the substrates 100.

In some embodiments, the lower portion 304 and the upper portion 306 may be made of stacked and heat welding Zotek composite material with various stiffness and softness. The advantages of the material are that the material is light weight, enabling the use of cheaper robots, and the composite structure is easily made by heat molding without any adhesive.

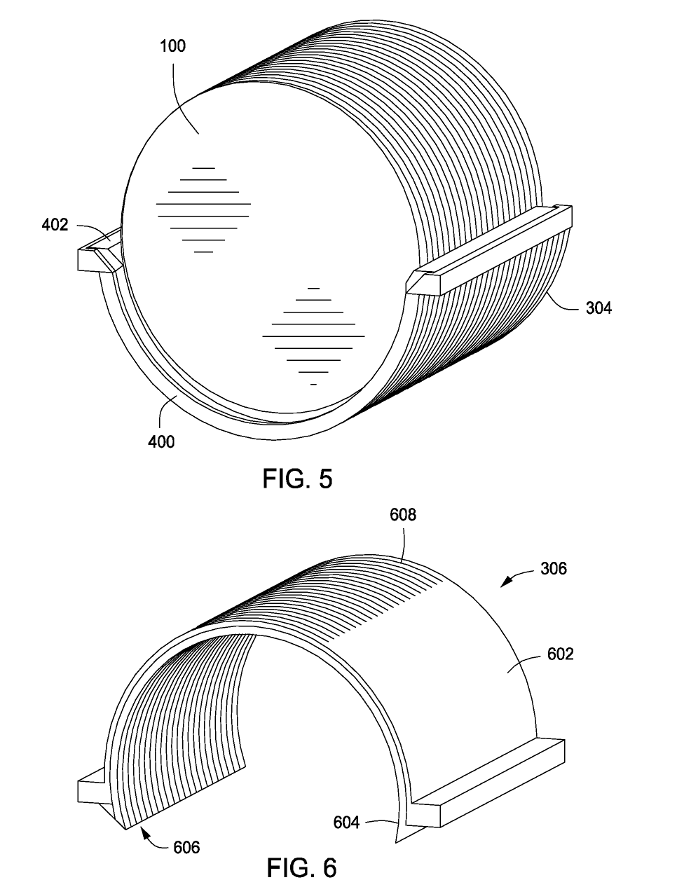

FIG. 4 depicts the lower portion 304 of the substrate holder 300. The lower portion 304 comprises a single integral concave body 400 to support one or more substrates. A first sealing material 402 coats an inner surface of the lower portion 304. The first sealing material 402 is a material suitable for forming a seal and resistant to a hydrogen fluoride solution. In some embodiments, the first sealing material 402 is polyvinylidene fluoride foam. A first plurality of grooves 404 is disposed in the first sealing material 402.

As depicted in FIG. 5, each of a plurality of substrates 100 are supported within each of the plurality of grooves 404. As depicted in FIG. 5, the plurality of substrates 100 are held substantially parallel to each other and with the front surface and back surface substantially perpendicular to the bottom of the lower portion. The grooves 404 in the first sealing material 402 support and seal the plurality of substrates 100 only at the perimeter of the substrates 100.

One advantage of the present system is the ability to obtain substantially uniform porous silicon coverage on the full surface of the substrate without any perimeter exclusions. Thus, embodiments of the present disclosure support the substrate such that no areas of the substrate perimeter are blocked or covered by any material that prevents uniform electric field distribution and direct contact with the bath chemistry. Some embodiments cover designs of mechanical features that can hold the wafer in place, but with zero to negligible contact points and blocking points on the wafer. The grooves 404 in the first sealing material 402 advantageously allow the chemical solution in a bath to contact the front surface and back surface of the substrates 100 to prevent a silicon-free zone from forming on the front surface and back surface of the substrates 100 proximate the substrate supporting area.

Returning to FIG. 4, the lower portion 304 comprises a first plurality of openings 406 disposed through the first sealing material 402 and through the concave body 400. In some embodiments, the first plurality of openings 406 is disposed between the first plurality of grooves 404. Chemicals flow through the first plurality of openings 406 to fill the lower portion 304 and immerse the substrates in an electrolyte bath when the substrate holder 300 is inserted into a chemical solution filled electrolyte bath such as depicted in FIG. 11.

At the stages of loading and unloading the starting wafers before and after porous Si formation, the pitch or space may advantageously agree with that of conventional substrate cassettes, with 6 mm in space between adjacent substrates of silicon (Si), that has been used for long time in the silicon (Si) integrated circuit (IC) industry. Alternatively, in some embodiments, a dual pitch of 12 mm may be used along with the conventional cassettes to load the substrates into the lower portion of the substrate holder. The substrates may be loaded by gravity by placing the substrate cassette over head of the lower portion and rotating the cassette 180 degree to drop the substrates into the lower portion automatically. Alternatively, the substrates may be loading from the cassettes by lifting the substrates by conventional substrate loading robot and transported into the lower portion.

FIG. 6 depicts the upper portion 306. The upper portion 306 comprises a convex body 602. In some embodiments, the convex body 602 is a single integral structure as depicted in FIG. 6. A second sealing material 604 coats an inner surface of the upper portion 306. Similar to the first sealing material 402 described above, the second sealing material 604 is a material suitable for forming a seal and resistant to a hydrogen fluoride solution. In some embodiments, the second sealing material 604 is polyvinylidene fluoride foam. A second plurality of grooves 606 is disposed in the second sealing material 604. In some embodiments, the second plurality of grooves 606 is disposed substantially opposite the first plurality of grooves 404. When the upper portion 306 is placed atop the lower portion 304, the plurality of substrates 100 are supported by each of the first plurality of grooves 404 and the second plurality of grooves 606. Similar to the first plurality of grooves 404, the second plurality of grooves 606 support and seal the substrates 100 only at the perimeter of the substrate 100 to advantageously allows the electrolyte bath chemicals to contact the front surface and back surface of the substrates 100 to prevent a silicon-free zone from forming on the front surface and back surface of the substrates 100 proximate the substrate supporting area. The upper portion 304 further comprises a second plurality of openings 608 disposed through the second sealing material 604 and through the convex body 602. In some embodiments, the second plurality of openings 608 is disposed between the second plurality of grooves 606 to allow the flow of chemical solution within the electrolyte bath.

FIG. 7 shows the intersection 700 of the first sealing material 402 and the second sealing material 604 around the substrate 100 when the upper portion 306 is disposed atop the lower portion 304. As depicted in FIG. 7, the first sealing material 402 has a tapered surface 702 configured to mate with a tapered surface 704 of the second sealing material 604. The tapered surfaces 702, 704 ensure a seal all around the substrate perimeter. Round shaped substrates advantageously minimize leakage at surrounding sealing areas and further improve sealing by utilizing tapered angles at the junction of the upper and lower portions at the middle of the substrate position.

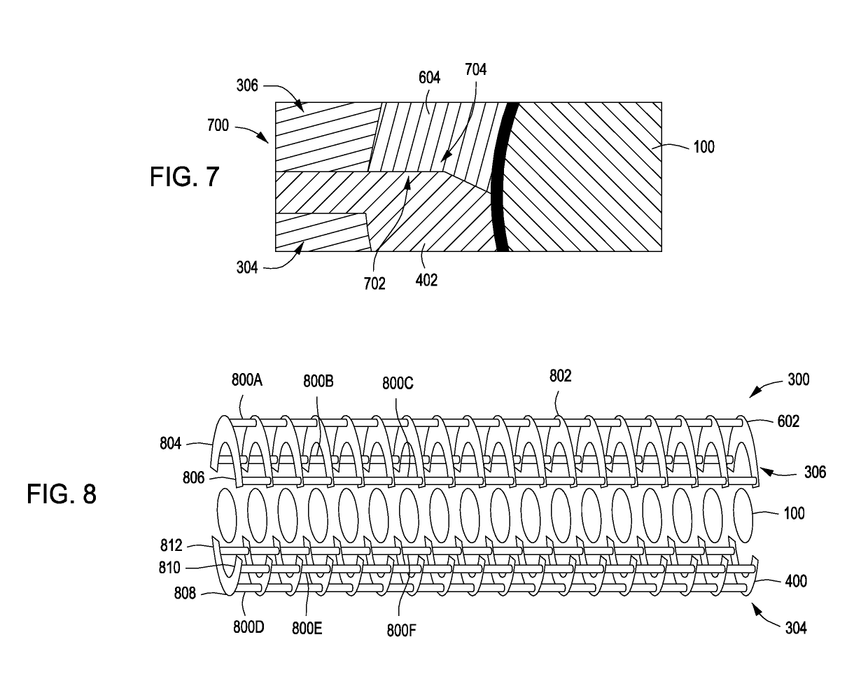

In some embodiments, as described above and as depicted in FIGS. 3A-3C, 4, 5, and 6, a single substrate holder 300 comprising a lower portion 304 and upper portion 306 having a single integral convex body 602 may hold a plurality of substrates 100. Alternatively, in some embodiments as depicted in FIG. 8, a plurality of linked substrate holders 300 may each hold a single substrate 100. As depicted in FIG. 8, each substrate holder 300 comprises an upper portion 306 and a lower portion 304. The details of the upper portion 306 and the lower portion 304 of each substrate holder 300 are as described above. Each substrate holder 300 may be linked together by one or more linking members 800. In some embodiments, as depicted in FIG. 8, a plurality of upper portions 306 are linked by three linking members 800A, 800B, 800C. In the embodiment depicted in FIG. 8 a linking member 800A is coupled to a top 802 of the convex body 602, linking members 800B is coupled to a first leg 804 of the convex body 602, and linking member 800C is coupled to a second leg 806 of the convex body 602. In some embodiments, as depicted in FIG. 8, a plurality of corresponding lower portions 304 are linked by three linking members 800D, 800E, 800F. In the embodiment depicted in FIG. 8 a linking member 800D is coupled to a bottom 808 of the concave body 400, linking members 800E is coupled to a first leg 810 of the concave body 400, and linking member 800F is coupled to a second leg 812 of the concave body 400. While FIG. 8 depicts one possible arrangement of the linking members 800, more or less linking members 800 may be used and may be coupled to the plurality of substrate holders 300 at varying points on the surface of the substrate holders 300. In some embodiments, the lower portion 304 and the upper portion 306 may have an attachment, such as a handle, for transportation by a robot into the bath depicted in FIG. 11.

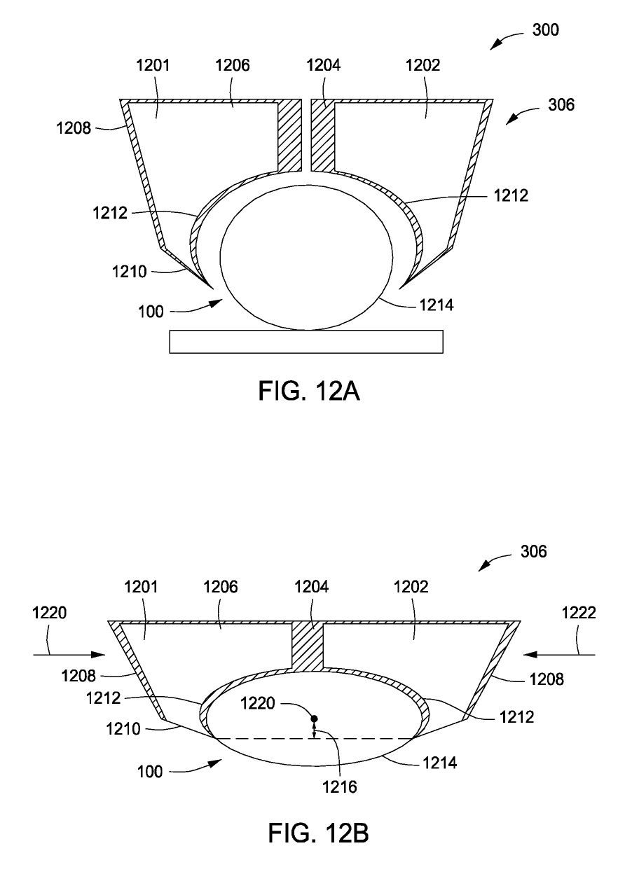

Alternately, in some embodiments, as depicted in FIG. 12A, an upper portion 306 of the substrate holder 300 comprises a first body 1201 and a second body 1202. In some embodiments, the first body 1201 and second body 1202 may be made of stacked and heat welding Zotek composite material with various stiffness and softness. In some embodiments, a third sealing material 1204 coats an outer surface of the first body 1201 and second body 1202. Similar to the first sealing material 402 and second sealing material 604 described above, the third sealing material 1204 is a material suitable for forming a seal and resistant to a hydrogen fluoride solution. In some embodiments, the third sealing material 1204 is polyvinylidene fluoride foam. The first body 1201 and second body 1202 comprise a top surface 1206, a tapered sidewall 1208, and a tapered bottom surface 1210. The first body 1201 and second body 1202 further comprises an inner concave surface 1212 to hold the substrate 100 along a portion of the perimeter1214 of the substrate 100. FIG. 12B shows the first body 1201 and second body 1202 holding the substrate 100 along a portion of the perimeter1214 of the substrate 100. A first force 1220 is applied to the first body 1201 along the tapered sidewall 1208 to move the first body 1201 toward the second body 1202 and a second force 1222 is applied to the second body 1202 along the tapered sidewall 1208 to move the second body 1202 toward the first body 1201 until a seal is formed by the inner concave surface 1212 around the perimeter1214 of the substrate 100. In some embodiments, as depicted in FIG. 12B, the tapered bottom surface 1210 extends a suitable distance 1216, for example about 30 mm, below the center 1224 of the substrate 100.

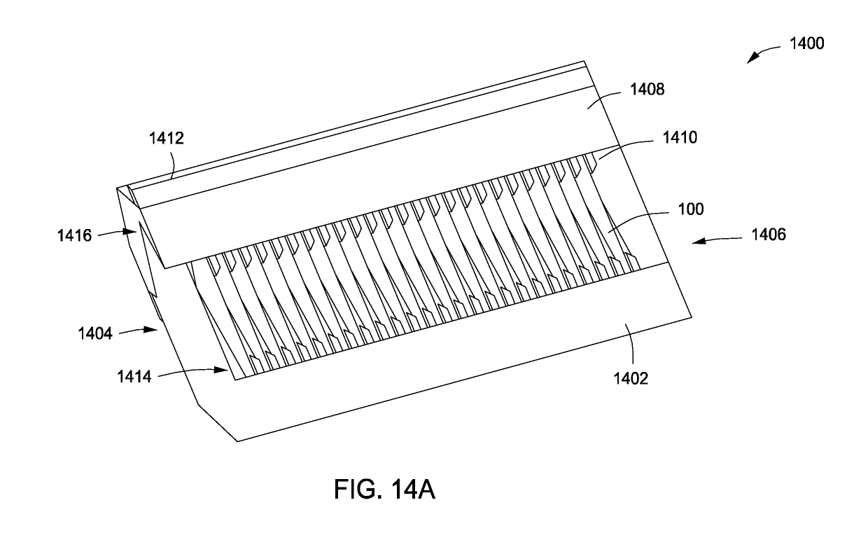

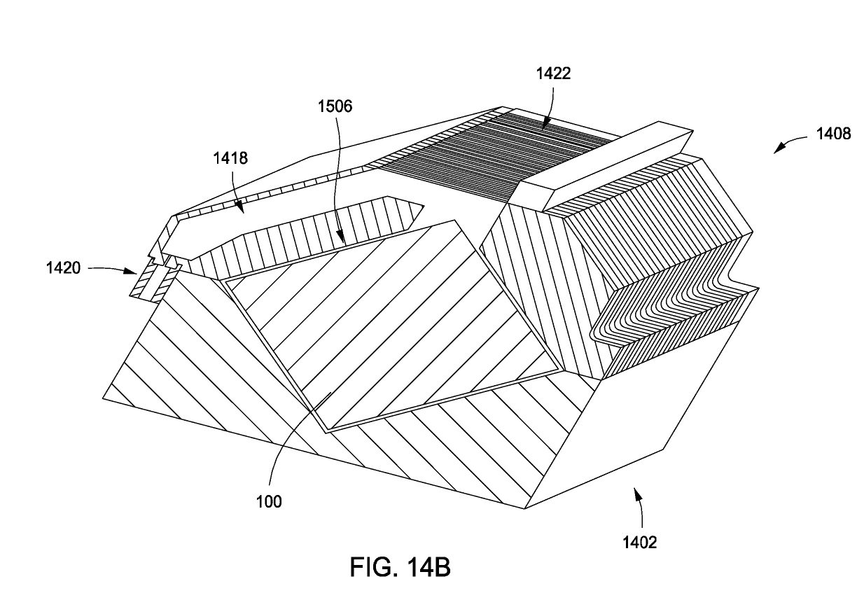

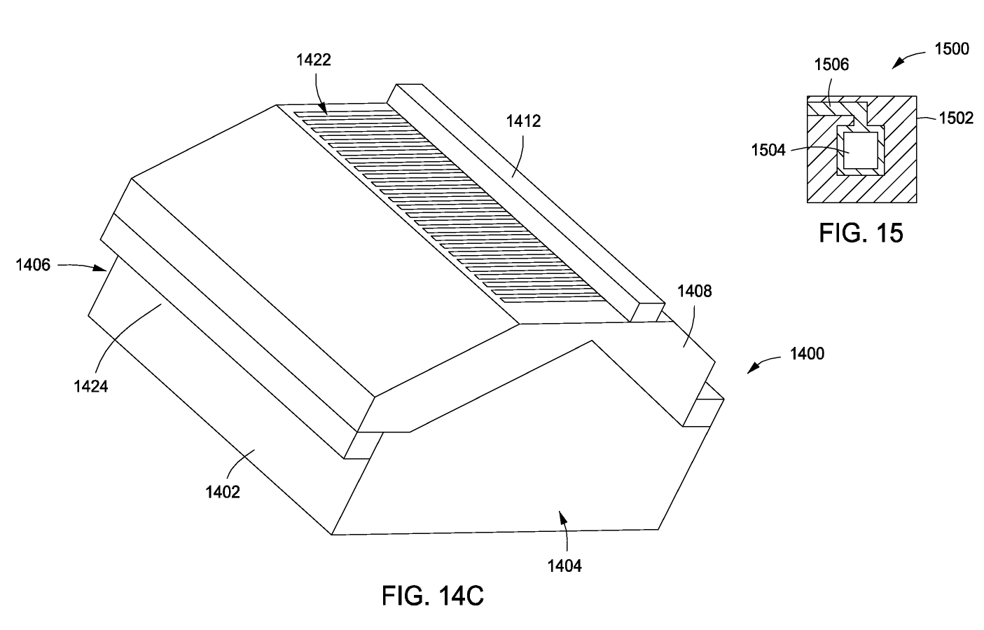

Alternatively, in some embodiments as depicted in FIGS. 14A-14C the substrate holder comprises a plurality of plates having a vacuum chuck to hold a plurality of substrates. FIG. 14A depicts a cross sectional view of a multi-wafer bath 1400 having a bottom portion 1402 and a detachable upper portion 1408. The upper portion 1408 and bottom portion 1402 may be composed of the same material as described with respect to embodiments discussed above. The bottom portion 1402 comprises an anode at first end 1404 and a cathode at a second end 1406. The upper portion 1408 comprises a plurality of structures 1410 to hold a plurality of substrates 100. As depicted in FIG. 14A, when the upper portion 1408 is coupled to the bottom portion 1402, each structure 1410 individually seals to the bottom surface of the bottom portion 1402, thus isolating chemical solution 1414 between each substrate from other substrates. In addition when the upper portion 1408 is coupled to the bottom portion 1402 a seal is formed at the interface 1416 to prevent leakage of chemical solution 1414.

The upper portion 1408 may be detached from the bottom portion 1402 to load substrates 100 into the plurality of structures 1410. In some embodiments, the plurality of structures 1410 may be a plurality of plates clamped together. As depicted in FIG. 15A, each plate 1500 is composed of a body 1502. In some embodiments, the body 1502 is made of polyvinylidene fluoride. The plate 1500 comprises an opening 1504 to hold a substrate 100. The substrate is held within the opening 1504 using vacuum pressure supplied by the vacuum manifold 1412 shown in FIG. 14A. The opening 1504 may be appropriately fashioned for substrates of various geometries such as, but not limited to round, square, pseudo square (square with truncated corners) with rounder corners of varying degrees, as well as rectangular structures. The body 1502 of the plate 1500 further comprises an overflow path 1506 cut into the front of each plate 1500 so that recirculating chemical solution 1414 is fully isolated per substrate 100.

FIG. 14B shows a sectional view of the upper portion 1408 coupled to the bottom portion 1402. The upper portion 1408 further comprises a plurality of openings 1422 for ventilation of gases formed during processing. FIG. 14B also shows an overflow path 1506 around the substrate 100 fluidly coupled to a drainage channel 1418 which is fluidly coupled to a drain outlet 1420. The drain outlet 1420 is fluidly coupled to a drain collector 1424 shown in FIG. 14C. The embodiment depicted in FIGS. 14A-14C and FIG. 15 advantageously eases substrate handling in a porous Si formation process by decoupling the processing from the substrate handling. One challenge with any porous silicon chamber is handling the hydrogen (H2) gas generated as a result of the anodic etch reaction. Hydrogen evolves from the surface of the substrate and each electrode. Since the bath is integral with electrical current transmission, H₂ gas blocks current flow and supply of chemicals to the reaction surface, thus affecting porous silicon formation and continuity/uniformity. Thus effective and rapid purge or sweep H₂ byproducts from the surfaces of the wafer and electrodes is advantageous. In the embodiment depicted in FIGS. 3A-3C, and FIGS. 4-6, hydrogen bubbles created by the porous silicon forming process can easily escape via the second plurality of openings 608 disposed through the second sealing material 604 and through the convex body 602 to vent openings over the bath structure. In the embodiments depicted in FIG. 8 and FIG. 12, where the substrates 100 are each separated by a space, hydrogen bubbles created by the porous silicon forming process can easily escape upward over the surface of the bath 302 to vent openings between the substrate holder segments. In the embodiment depicted in FIGS. 14A-14C, hydrogen bubbles created by the porous silicon forming process can easily escape via the plurality of openings 1422 which advantageously enables minimization of the space and pitches between substrates and maximizes the number of the substrates in a bath, resulting in more uniform formation of porous silicon layers all over the substrate surface at a higher throughput and yield while providing a lower cost by decreasing chemical consumption volume per substrate. As depicted in FIG. 11, the vent openings are located over the chemical surface in the bath in order to advantageously prevent anodizing current leaking through vent opening in between the substrates as when vent openings are located within the chemicals in the bath.

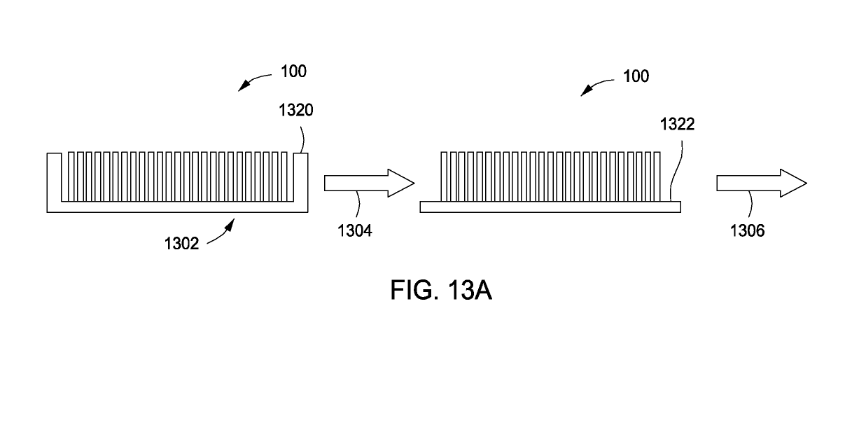

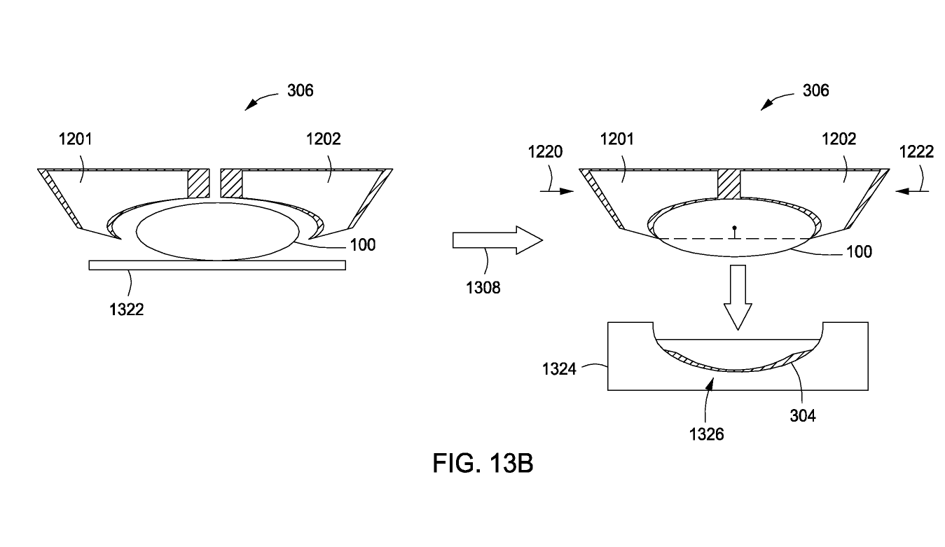

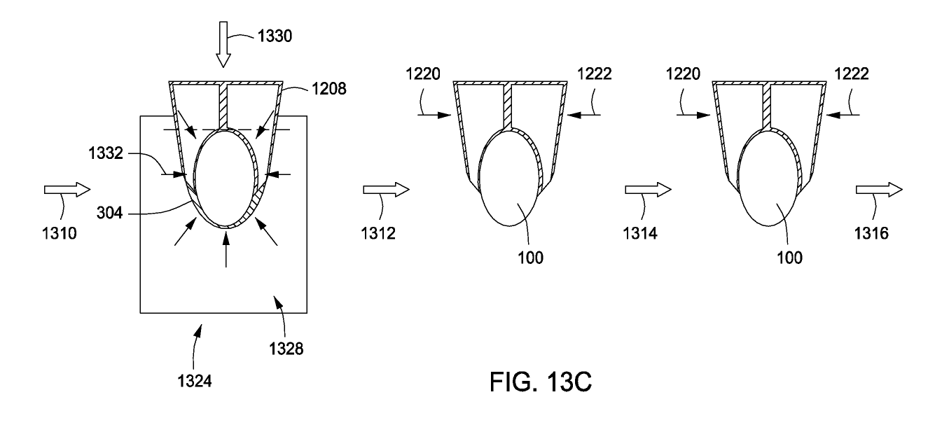

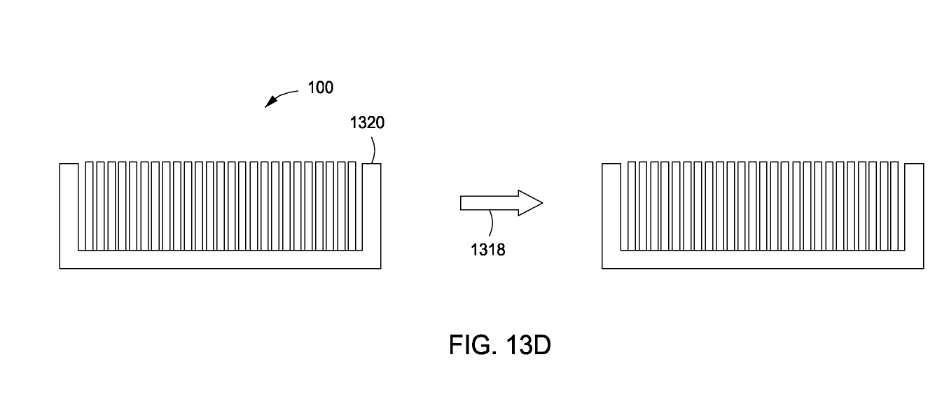

FIG. 13A-13D depicts a method of transferring substrates into and out of a bath structure, such as depicted in FIG. 11, for porous Si formation using a substrate holder 300 as depicted in FIGS. 12A-12B. At 1302, a standard cassette 1320 (shown in side view) holding a plurality of substrates 100, for example 25 substrates at 8 mm pitch is provided. Other suitable pitches, for example 6 mm or 12 mm may be used. Next, at 1304, the substrates 100 are transferred to a substrate alignment tray 1322 for notch alignment. The substrates may be transferred, for example, using a transfer robot. Next at 1306, an upper portion 306 (shown in front view) of a substrate holder 300 comprising a plurality of first bodies 1201 and a plurality of second body 1202, as described above with respect to FIGS. 12A-12B, is oriented above the plurality of substrates 100. Next at 1308, the upper portion 306 holds the plurality of substrates 100 above the bath 1324, in some embodiments a bath as described with respect to FIG. 11. As described with respect to FIG. 12B, a first force 1220 is applied to each of the plurality of first bodies 1201 to move each first body 1201 toward each corresponding second body 1202 and a second force 1222 is applied to the plurality of second bodies1202 to move each second body 1202 toward each corresponding first body 1201 until a seal is formed around the perimeter 1214 of the plurality of substrates 100. The lower portion 304 of the substrate holder 300 is disposed along the bottom surface 1326 of the bath 1324. In some embodiments, the lower portion 304 remains in the bath 1324. In some embodiments, the lower portion 304 may be configured as described above with respect to FIGS. 3A-3C, and FIGS. 4 and 5. In some embodiments, the lower portion may be configured as shown in FIG. 8. Next at 1310, the upper portion 306 holding the plurality of substrates 100 is lowered into the bath 1324 to immerse the substrates in the chemical solution 1328. The portion of the plurality of substrates 100 not held by the upper portion 306 are slotted into the lower portion 304 of the substrate holder 300. In some embodiments, the inner side walls of the bath may have grooves (not shown) or appropriately tapered sidewalls to guide the upper portion 306 into the proper position over the lower portion 304. A downward force 1330 is applied to the top of the upper portion 306 such that the tapered sidewalls 1208 and lower portion 304 apply a substantially uniform force 1332 to the perimeter of the plurality of substrates 100, thus preventing leakage between each substrate. Anodization takes place by applying current to electrodes located at opposing walls in the bath as depicted in FIG. 11. Next at 1312, once the porous Si formation is complete, the plurality of substrates 100 are removed from the bath 1324 and subjected to an isopropyl alcohol (IPA) rinse. Next at 1314, following the IPA rinse the plurality of substrates 100 are subjected to a deionizing (DI) water, quick dump rinse (QDR) rinse. Next at 1316, following the DI water QDR the plurality of substrates 100 are transferred to a standard cassette 1320. Next at 1318, the plurality of substrates 100 are subjected to a spin drying process.

The batch porous silicon equipment design embodiments described above can be used to form either single-layer or multi-layer porous silicon on one or both sides of the substrates in the batch. Porous silicon can be formed on only one side of the substrates by applying the electrical current flowing in only one direction without a change in the current polarity. On the other hand, porous silicon can be formed on both sides of the substrates by alternating the current flow direction at least once or multiple times. The electrical current density (in conjunction with the HF concentration) controls the layer porosity. Thus, the layer porosity can be increased by increasing the electrical current density and conversely can be reduced by reducing the electrical current density. Multi-layer porous silicon can be formed by modulating or changing the electrical current level in time during the porous silicon formation process. For instance, starting the porous silicon process with a lower current density followed by a higher current density results in formation of a lower porosity layer on top of a higher porosity buried layer. A graded porosity porous silicon layer can be formed by, for instance, linearly modulating or varying the electrical current density in time. One can use the approach herein to form any porous silicon structure with 1 to many porous silicon layers with 1 to many porosity values.

While the foregoing is directed to embodiments of the present disclosure, other and further embodiments of the disclosure may be devised without departing from the basic scope thereof.

1. An anodizing bath, comprising
(a) a housing having a first volume to hold a chemical solution and a longitudinal axis along a length of the housing;
(b) a cathode disposed within the first volume at a first side of the housing;
(c) an anode disposed within the first volume at a second side of the housing, opposite the first side, wherein a face of each of the cathode and the anode have a given surface area;
(d) a substrate holder configured to retain a plurality of substrates along a perimeter of the substrates within the first volume in a plurality of substrate holding positions in an orientation such that faces of the substrates are substantially normal to the longitudinal axis,
wherein the substrate holder is configured to retain substrates having a given surface area of a face of the substrate that is substantially equal to the given surface area of the faces of the anode and cathode,
wherein a first substrate holding position is disposed at a first distance from the cathode, a second substrate holding position is disposed at a second distance from the anode, and remaining substrate holding positions are disposed between the first and second substrate holding positions, wherein the first distance and the second distance are each less than or equal to a distance between adjacent ones of the plurality of substrate holding positions,
wherein the substrate holder forms a seal around a perimeter of each substrate to form a plurality of second volumes between adjacent pairs of the plurality of substrates when substrates are disposed within the substrate holder; and
(e) a plurality of vent openings fluidly coupled to the first volume to release process gases, wherein a top of each of the plurality of vent openings are disposed above a chemical solution fill level in the first volume.

2. The anodizing bath of claim 1, wherein the first volume comprises:
a third volume disposed between the first substrate holding position and the cathode; and
a fourth volume disposed between the second substrate holding position and the anode;
wherein chemical solution at or below the chemical solution fill level is isolated between each of the second volumes, third volume, and fourth volume.

3. The anodizing bath of claim 1, wherein the substrate holder comprises:
a lower portion having an integral concave body composed of a sealing material;
a first plurality of grooves disposed in the integral concave body of the lower portion and configured to support the plurality of substrates;
an upper portion disposed atop the lower portion and having an integral convex body composed of a sealing material, wherein the integral convex body comprises an inner surface configured to form a seal along a perimeter of a substrate disposed in a first plurality of grooves of the lower portion
a second plurality of grooves disposed in the integral convex body of the upper portion and disposed substantially opposite the first plurality of grooves; and
a plurality of openings disposed through the integral convex body of the upper portion to release process gases.

4. The anodizing bath of claim 3, wherein the first plurality of grooves disposed in the integral concave body of the lower portion and the second plurality of grooves disposed in the integral convex body of the upper portion are configured to support a plurality of substrates substantially parallel to each other.

5. The anodizing bath of claim 3, wherein the first plurality of grooves disposed in the integral concave body of the lower portion and the second plurality of grooves disposed in the integral convex body of the upper portion support each of the plurality of substrates only at the perimeter of the substrate.

6. The anodizing bath of claim 3, wherein the plurality of openings disposed through the integral convex body of the upper portion are disposed between each of the plurality of substrates supported by the substrate holder.

7. The anodizing bath of claim 1, wherein the substrate holder comprises:
a plurality of lower portions each having a concave body composed of a sealing material and a groove disposed in each of the concave bodies of the lower portion and configured to support a substrate;
a plurality of upper portions each having a convex body composed of a sealing material, wherein each upper portion is configured to be disposed atop a corresponding lower portion, and wherein each convex body comprises an inner surface configured to form a seal around the perimeter of a substrate disposed in a groove of the concave body of the corresponding lower portion;
one or more linking members coupled to the plurality of lower portions; and
one or more linking members coupled to the plurality of upper portions, wherein upper portion and corresponding lower portion are spaced a first distance from a subsequent upper portion and corresponding lower portion to allow for a release of process gases.

8. The anodizing bath of claim 7, wherein each convex body of the plurality of upper portions is integrally formed.

9. The anodizing bath of claim 7, wherein each convex body of the plurality of upper portions comprises a first body and a second body composed of a sealing material.

10. The anodizing bath of claim 9, wherein the first body and the second body comprise:
a top surface,
a tapered sidewall,
a tapered bottom surface; and
an inner concave surface to hold the substrate along a portion of a perimeter of the substrate.

11. The anodizing bath of claim 1, wherein the substrate holder comprises:
a plurality of plates coupled together, wherein each plate comprises a body having an opening to retain a substrate via vacuum pressure.

12. The anodizing bath of claim 11, wherein each body comprises:
a fluid flow path formed in a first surface of each plate; and
an outer edge configured to form a seal with an inner surface of the housing.

13. A method of transferring substrates into an anodizing bath of claim 1, comprising:
providing a cassette holding a plurality of substrates a first distance apart;
transferring the plurality of substrates from the cassette to a substrate alignment tray;
orienting an upper portion of a substrate holder above the plurality of substrates, wherein the upper portion of the substrate holder comprises a plurality of first bodies and a corresponding plurality of second bodies;
applying a first force to each first body to move each first body toward each corresponding second body;
applying a second force to each second body to move each second body toward each corresponding first body until each first body and second body form a seal around a perimeter of each substrate;
lowering the upper portion into a housing having a first volume configured to hold a chemical solution to immerse the substrates in a chemical solution, wherein the first volume comprises a lower portion of the substrate holder disposed along a bottom surface of the housing;
applying a force to the upper portion of the substrate holder in a direction perpendicular to the bottom surface of the housing while the substrates are immersed in the chemical solution;
applying a current to a cathode disposed within the first volume at a first end of the housing and to an anode disposed within the first volume at a second end of the housing, opposite the first end to form porous Si on the substrates, wherein a diameter of the cathode and the anode is equal to the diameter of the substrates;
removing the substrates from the housing;
exposing the substrates to an isopropyl alcohol rinse;
exposing the substrates to a deionizing water, quick dump rinse; and
exposing the substrates to a spin drying process.

14. The method of claim 13, wherein the lower portion remains in the housing.

15. The method of claim 13, wherein a portion of the substrates not held by the upper portion are held by the lower portion of the substrate holder.

16. An anodizing bath, comprising:
(a) a housing having a first volume to hold a chemical solution to a designated fill level and a longitudinal axis along a length of the housing;
(b) a cathode disposed within the first volume proximate a first side of the housing;
(c) an anode disposed within the first volume proximate a second side of the housing, opposite the first side;
(d) a substrate holder configured to retain a plurality of substrates along a perimeter of the substrates within the first volume in a plurality of linearly arranged substrate holding positions in an orientation such that faces of the substrates are substantially normal to the longitudinal axis, wherein the substrate holder forms a seal around a perimeter of each substrate to form a plurality of second volumes between adjacent pairs of the plurality of substrates when substrates are disposed within the substrate holder, wherein the plurality of second volumes are electrically isolated from the first volume; and
(e) a plurality of vent openings fluidly coupled to the first volume to release process gases, wherein a top of each of the plurality of vent openings are disposed above the fill level in the first volume.

17. The anodizing bath of claim 16, wherein the first volume comprises:
a third volume disposed between the cathode and a first substrate holding position closest to the cathode; and
a fourth volume disposed between the anode and a second substrate holding position closest to the anode, wherein chemical solution at or below the fill level is isolated between each of the plurality of second volumes, the third volume, and the fourth volume.

18. The anodizing bath of claim 16, wherein the substrate holder comprises:
a lower portion having an integral concave body composed of a sealing material;
a first plurality of grooves disposed in the integral concave body and configured to support the plurality of substrates;
an upper portion disposed atop the lower portion and having an integral convex body composed of a sealing material, wherein the integral convex body comprises an inner surface configured to form a seal along a perimeter of each substrate disposed in a first plurality of grooves of the lower portion
a second plurality of grooves disposed in the integral convex body of the upper portion and disposed substantially opposite the first plurality of grooves; and
a plurality of openings disposed through the integral convex body of the upper portion to release process gases.

19. The anodizing bath of claim 18, wherein the first plurality of grooves disposed in the integral concave body of the lower portion and the second plurality of grooves disposed in the integral convex body of the upper portion are configured to support a plurality of substrates substantially parallel to each other.

20. The anodizing bath of claim 18, wherein the first plurality of grooves disposed in the integral concave body of the lower portion and the second plurality of grooves disposed in the integral convex body of the upper portion support each of the plurality of substrates only at the perimeter of the substrate.
